(19) United States
(12) Patent Application Publication
(10) Pub. No.: US 2005/0012113 A1
(43) Pub. Date: Jan. 20, 2005

(54) [UV PHOTODETECTOR]

(76) Inventors: JINN-KONG SHEU, TAINAN COUNTY (TW); WEI-CHIH LAI, CHIAI (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/707,084

(22) Filed: Nov. 20, 2003

(30) Foreign Application Priority Data
Jul. 17, 2003 (TW) 92119489

(51) Int. Cl. H01L 31/0328; H01L 31/109

(52) U.S. Cl. 257/184; 257/190; 257/452; 257/457; 257/459; 257/461

(57) ABSTRACT

An UV photo-detector having a GaN-based interlayer is provided. Because of the excellent insulating property of the GaN-based interlayer and an excellent Schottky contact between the GaN-based interlayer and electrodes of the device, the leakage current of the device is substantially reduced. For example, the material of the GaN-based interlayer includes AlₓIn_{y}Ga_{1-x-y}N, in which x≧0, y≧0, 1≧x+y. The GaN-based interlayer described above is manufactured without requiring a high temperature treatment process after the epitaxy process, and thus the process flow is simplified. Therefore, an UV photodetector having an excellent performance is obtained.

### CROSS REFERENCE TO RELATED APPLICATIONS

This application claims the priority benefit of Taiwan application serial no.92119489, filed on Jul. 17, 2003.

### BACKGROUND OF INVENTION

1. Field of the Invention

The present invention relates to an ultraviolet (UV) photodetector. More particularly, the present invention relates to an UV photodetector having a high-resistivity GaN-based interlayer for reducing the leakage current.

2. Description of the Related Art

In general, a conventional UV photodetector can be classified into three type of devices including a photomultiplier Tube (PMT), a silicon-based UV photodetector and a III-V compound semiconductor UV photodetector such as a GaN UV photodetector. Currently, only the photomultiplier tube and the silicon-based UV photodetector are commercialized and produced under mass production. The GaN UV photodetector is just under a preliminary research and development due to the high cost and the complicated technique.

In general, the shortcoming of a photomultiplier tube is that the cost is high, the operational voltage is high, and the vacuum tube is fragile, but the advantage is that a precise detecting result can be obtained. The advantage of the silicon-based UV photodetector is that the manufacturing process is simple, the cost is low, the operation voltage is low, and a wavelength of light in visible and infrared can be detected, but the disadvantages are that the rejection ratio of ultraviolet to visible and/or infrared is poor. The advantage of the GaN UV photodetector is that the detecting wavelength of the detector can be adjusted according to the needs during the manufacturing process. For example, when the desired detecting wavelength is set in a range of about 200 nm to about 365 nm, an excellent detecting sensitivity for AlGaN-based UV photodetector can be obtained by adjusting the Al composition of AlGaN absorption layer. Therefore, the AlGaN-based UV photodetector has become the major trend of the UV photodetector in recent years.

FIG. 1 is cross-sectional view illustrating a conventional Schottky barrier diode (SBD) type UV photodetector. Referring to FIG. 1, a conventional Schottky barrier diode type UV photodetector is at least constructed by a substrate 100, a GaN-based semiconductor layer 102, a first electrode 104 and a second electrode 106. The GaN-based semiconductor layer 102 is disposed on the substrate 100, and the GaN-based semiconductor layer 102 has a first protrusion portion A. The first electrode 104 is disposed on the first protrusion portion A of GaN-based semiconductor layer 102, and the second electrode 106 is disposed on a portion of the GaN-based semiconductor layer 102 except for the first protrusion portion A. In addition, the first bonding pad 108 and the second bonding pad 110 are disposed on the first electrode 104 and the second electrode 106 respectively.

Referring to FIG. 1, the GaN-based semiconductor layer 102 is generally constructed by a nucleation layer 102a, an ohmic contact layer 102b and an active layer 102c. The nucleation layer 102a is disposed on the substrate 100. The ohmic contact layer 102b is disposed on the nucleation layer 102a, and the ohmic contact layer 102b has a second protrusion portion B. The active layer 102c is disposed on the second protrusion portion B. According to the structure described above, the first protrusion portion A of the whole GaN-based semiconductor layer 102 is constructed by the second protrusion portion B of the ohmic contact layer 102b and the active layer 102c.

FIG. 2 is a perspective view illustrating a conventional metal-semiconductor-metal (MSM) type UV photodetector. Referring to FIG. 2, a conventional metal-semiconductor-metal (MSM) type UV photodetector is constructed by a substrate 200, a GaN-based semiconductor layer 202 and a patterned electrode layer 204. The GaN-based semiconductor layer 202 is disposed on the substrate 200. The patterned electrode layer 204 is disposed on the GaN-based semiconductor layer 202. Moreover, the GaN-based semiconductor layer 202 is constructed from a nucleation layer 202a and an active layer 202b. The nucleation layer 202a is disposed on the substrate 200, and the active layer 202b is disposed on the nucleation layer 202a.

Referring to FIG. 2, the patterned electrode layer 204 is constructed by a first electrode 206 and a second electrode 208, and a first bonding pad 210 and a second bonding pad 212 are disposed on the first electrode 206 and the second electrode 208 respectively. Moreover, the first electrode 206 has a plurality of mutually parallel aligned first finger-shaped protrusions 206a, and the second electrode 208 has a plurality of mutually parallel aligned second finger-shaped protrusions 208a. These first finger-shaped protrusions 206a and second finger-shaped protrusion 208a are mutually interlaced.

In a conventional UV photodetector, whether in a Schottky barrier diode (SBD) type UV photodetector, or in a metal-semiconductor-metal (MSM) type UV photodetector, there is an issue of a high leakage current. The leakage current is caused by the thermal emission effect and/or the extraordinary tunneling effect due to the poor Schottky contact property between the semiconductor layer and the electrode. Therefore, if the performance of the Schottky contact between the semiconductor layer and the electrode can be effectively enhanced, the leakage current of the UV photodetector will be drastically reduced.

### SUMMARY OF INVENTION

Accordingly, the purpose of the present invention is to provide a Schottky barrier diode (SBD) type UV photodetector that can effectively reduce the leakage current.

It is another object of the present invention to provide a metal-semiconductor-metal (MSM) type UV photodetector that can effectively reduce the leakage current.

In order to achieve the above objects and other advantages of the present invention, a Schottky barrier diode (SBD) type UV photodetector is provided. The UV photodetector is at least constructed by a substrate, a GaN-based semiconductor layer, a GaN-based interlayer, a first electrode and a second electrode. The GaN-based semiconductor layer is disposed on the substrate, and the GaN-based semiconductor layer has a first protrusion portion. The GaN-based interlayer is disposed on the first protrusion portion of the GaN-based semiconductor layer, and a material of the GaN-based interlayer includes, for example but not limited to, an AlₓIn_{y}Ga_{1-x-y}N, wherein x≧0, y≧0, and 1≧x+y. The first electrode is disposed on the GaN-based interlayer, and the second electrode is disposed on a portion of the GaN-based semiconductor layer except for the first protrusion portion. In addition, in the above-described embodiment of the invention, the first bonding pad and the second bonding pad can be disposed on the first electrode and second electrode respectively.

In the Schottky barrier diode (SBD) type UV photodetector of the preferred embodiment, the substrate includes, for example but not limited to, an aluminum oxide (sapphire) substrate, a silicon carbide (SiC) substrate, a zinc oxide (ZnO) substrate, a silicon substrate, a gallium phosphide (GaP) substrate, and a gallium arsenide (GaAs) substrate.

In the Schottky barrier diode (SBD) type UV photodetector of the preferred embodiment, the GaN-based semiconductor layer, for example, is constructed from a nucleation layer, an ohmic contact layer and an active layer. The nucleation layer is disposed on the substrate. The ohmic contact layer is disposed on nucleation layer, and has a second protrusion portion. The active layer is disposed on the second protrusion portion. The first protrusion portion of the whole GaN-based semiconductor layer is constructed by the second protrusion portion of the ohmic contact layer and the active layer. Moreover, a material of the nucleation layer includes, for example but not limited to, AlₐIn_{b}Ga_{1-a-b}N semiconductor, wherein a, b≧0 and 0≦a+b≦1. The material of the ohmic contact layer includes, for example but not limited to, N-type Al_{c}In_{d}Ga_{1-c-d}N semiconductor, wherein c, d≧0 and 0≦c+d≦1. The material of the active layer includes, for example but not limited to, undoped AlₑIn_{f}Ga_{1-e-f}N semiconductor, wherein e, f≧0 and 0≦e+f≦1.

In the Schottky barrier diode (SBD) type UV photodetector of the preferred embodiment, the materials of the first electrode and the second electrode include, for example but not limited to, Ni/Au, Cr/Au, Cr/Pt/Au, Ti/Al, Ti/Al/Ti/Au, Ti/Al/Pt/Au, Ti/Al/Ni/Au, Ti/Al/Ti/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au Nd/Al/Co/A, Hf/Al/Ti/Au, Hf/Al/Pt/Au, Hf/Al/Ni/Au, Hf/Al/Pd/Au, Hf/Al/Cr/Au, Hf/Al/Co/Au, Zr/Al/Ti/Au, Zr/Al/Pt/Au, Zr/Al/Ni/Au, Zr/Al/Pd/Au, Zr/Al/Cr/Au, Zr/Al/Co/Au, TiNₓ/Ti/Au, TiNₓ/Pt/Au, TiNₓ/Ni/Au, TiNₓ/Pd/Au, TiNₓ/Cr/Au, TiNₓ/Co/Au, TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAl/Ni/Au, Ti/NiAl/Cr/Au, N-type conductive indium tin oxide (ITO), cadmium tin oxide (CTO), aluminum zinc oxide (ZnO:Al), indium zinc oxide (ZnO:ln),zinc gallate (ZnGa₂O₄), SnO₂:Sb, Ga₂O₃:Sn, AglnO₂:Sn, In₂O₃:Zn, P-type conductive CuAlO₂, LaCuOS, NiO, CuGaO₂ or SrCu₂O₂.

In order to achieve the above objects and other advantages of the present invention, a metal-semiconductor-metal (MSM) type UV photodetector is provided. The UV photodetector is constructed by a substrate, a GaN-based semiconductor layer, a GaN-based interlayer and a patterned electrode layer. The GaN-based semiconductor layer is disposed on substrate. The GaN-based interlayer is disposed on GaN-based semiconductor layer, and a material of GaN-based interlayer includes, for example but not limited to, AlₓIn_{y}Ga_{1-x-y}N semiconductors, wherein x≧0, y≧0, and 1≧x+y. The patterned electrode layer is disposed on GaN-based interlayer. In addition, the patterned electrode layer of embodiment described above is constructed by a first electrode and a second electrode respectively.

In the metal-semiconductor-metal (MSM)type UV photodetector of the preferred embodiment, the first electrode, for example, has a plurality of first finger-shaped protrusions which are mutually parallel aligned, and the second electrode, for example, has a plurality of second finger-shaped protrusions which are mutually parallel aligned. Moreover, the first finger-shaped protrusions and second finger-shaped protrusions, for example, are mutually interlaced.

In the metal-semiconductor-metal type UV photodetector of the present embodiment, the substrate includes, for example but not limited to, an aluminum oxide (sapphire) substrate, a silicon carbide (SiC)substrate, a zinc oxide (ZnO) substrate, a silicon substrate, a gallium phosphide (GaP) substrate, and a gallium arsenide (GaAs) substrate.

In the metal-semiconductor-metal type UV photodetector of the present embodiment, the GaN-based semiconductor layer, for example is constructed from a nucleation layer and an active layer. The nucleation layer is disposed on the substrate, and the active layer is disposed on the nucleation layer. Moreover, a material of the nucleation layer includes, for example, but not limited to, an AlₐIn_{b}Ga_{1-a-b}N semiconductor, wherein a, b≧0 and 0≦a+b≦1. The material of the active layer includes, for example but not limited to, an undoped AlₑIn_{f}Ga_{1-e-f}N semiconductor, wherein e, f≧0 and 0≦e+f≦1.

In the metal-semiconductor-metal type UV photodetector of the present embodiment, a material of the patterned electrode layer includes, for example, but not limited to, Ni/Au, Cr/Au, Cr/Pt/Au, Ti/Al, Ti/Al/Ti/Au, Ti/Al/Pt/Au, Ti/Al/Ni/Au, Ti/Al/Ti/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au Nd/Al/Co/A, Hf/Al/Ti/Au, Hf/Al/Pt/Au, Hf/Al/Ni/Au, Hf/Al/Pd/Au, Hf/Al/Cr/Au, Hf/Al/Co/Au, Zr/Al/Ti/Au, Zr/Al/Pt/Au, Zr/Al/Ni/Au, Zr/Al/Pd/Au, Zr/Al/Cr/Au, Zr/Al/Co/Au, TiNₓ/Ti/Au, TiNₓ/Pt/Au, TiNₓ/Ni/Au, TiNₓ/Pd/Au, TiNₓ/Cr/Au, TiNₓ/Co/Au, TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAl/Ni/Au, Ti/NiAl/Cr/Au, N-type conductive indium tin oxide (ITO), cadmium tin oxide (CTO), aluminum zinc oxide (ZnO:Al), indium zinc oxide (ZnO:In),, zinc gallate (ZnGa₂O₄), SnO₂:Sb, Ga₂O₃:Sn, AglnO₂:Sn, In₂O₃:Zn, P-type conductive CuAlO₂, LaCuOS, NiO, CuGaO₂ or SrCu₂O₂.

Accordingly, in the present invention, since a high-resistivity GaN-based interlayer is provided, the leakage current of the UV photodetector is thus reduced, and therefore, the performance of the device of the UV photodetector can be enhanced. Moreover, a thermal treatment process after the epitaxy process is not required in the manufacturing of the high-resistivity GaN-based interlayer, therefore the process can be simplified.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The following drawings illustrate embodiments of the invention and, together with the description, serve to explain the principles of the invention.

FIG. 1 is cross-sectional view illustrating a conventional Schottky barrier diode (SBD) type UV photodetector.

FIG. 2 is a perspective view illustrating a conventional metal-semiconductor-metal (MSM) type UV photodetector.

FIG. 3 is cross-sectional view illustrating a Schottky barrier diode (SBD) type UV photodetector according to a preferred embodiment of the present invention.

FIG. 4 is a diagram illustrating the current-voltage curves of the Schottky barrier diode (SBD) type UV photodetector of the present invention in comparison with that of a prior art measured under non-illuminated condition.

FIG. 5 is a perspective view illustrating a metal-semiconductor-metal (MSM) type UV photodetector according to a preferred embodiment of the present invention.

FIG. 6 is a diagram illustrating the current-voltage curves of the metal-semiconductor-metal (MSM) type UV photodetector of the present invention in comparison with that of a prior art measured under non-illuminated condition.

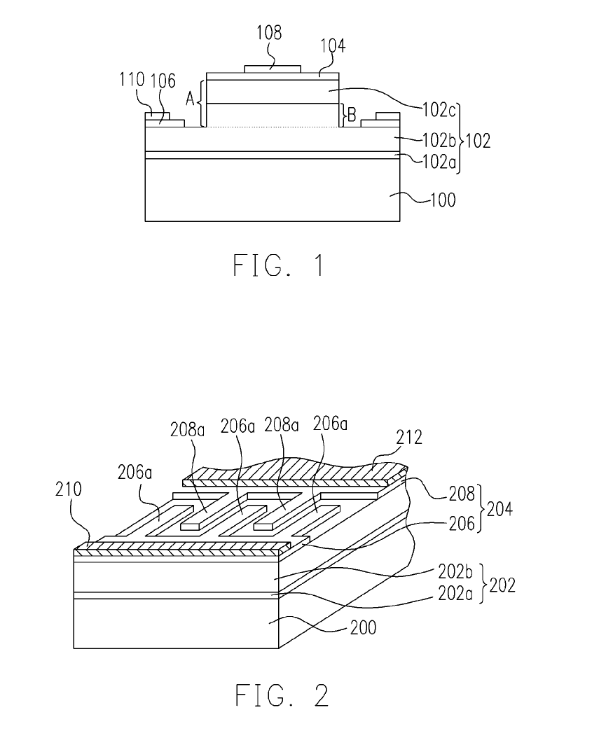

### DETAILED DESCRIPTION

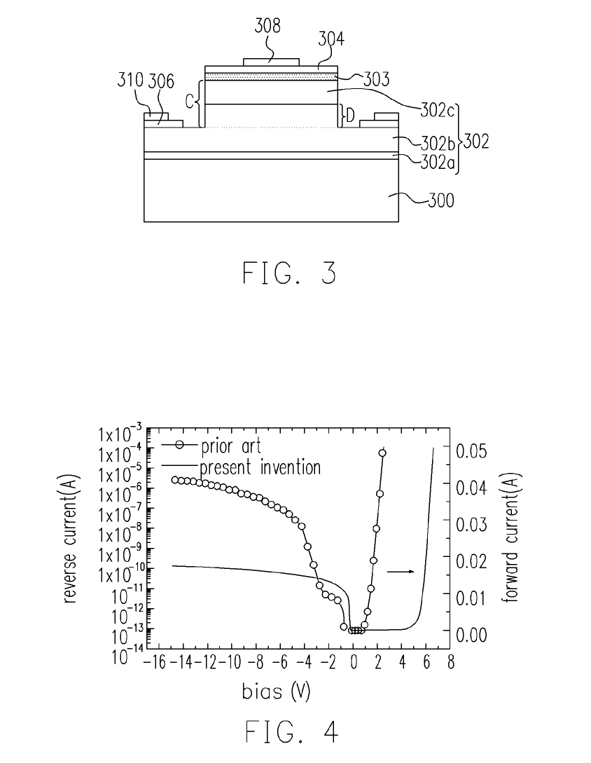

FIG. 3 is cross-sectional view illustrating a Schottky barrier diode (SBD) type UV photodetector according to a preferred embodiment of the present invention. Referring to FIG. 3, a Schottky barrier diode (SBD) type UV photodetector comprises a substrate 300, a GaN-based semiconductor layer 302, a high-resistivity GaN-based interlayer 303, a first electrode 304 and a second electrode 306. The GaN-based semiconductor layer 302 is disposed on the substrate 300, and the GaN-based semiconductor layer 302 has a first protrusion portion C. The GaN-based interlayer 303 is disposed on the first protrusion portion C of the GaN-based semiconductor layer 302, and the material of the GaN-based interlayer 303 includes, for example but not limited to, AlₓIn_{y}Ga_{1-x-y}N, wherein x≧0, y≧0, and 1≧x+y. The first electrode 304 is disposed on the GaN-based interlayer 303, and the second electrode 306 is disposed on a portion of the GaN-based semiconductor layer 302 except for the first protrusion portion C. Moreover, in order to simplify the package process, in the embodiment described above, it is optional that a first bonding pad 308 and a second bonding pad 310 are disposed on the first electrode 304 and the second electrode 306 respectively for the progress of the wire bonding process. The material of the first bonding pad 308 and the second bonding pad 310 includes, for example but not limited to, Ti/Au, Cr/Au, Cr/Pt/Au, or another material that can be incorporated with the first electrode 304 and the second electrode 306.

In the present embodiment, the substrate 300 includes, for example, but not limited to, an aluminum oxide (sapphire) substrate, a silicon carbide (SiC)substrate, a zinc oxide (ZnO) substrate, a silicon substrate, a gallium phosphide (GaP) substrate, and a gallium arsenide (GaAs) substrate. The high-resistivity interlayer 303 of the present embodiment is constructed by, for example but not limited to, doping at least one dopant selected from a group consisting of iron (Fe), magnesium (Mg), zinc (Zn), copper (Cu), arsenide (As), phosphorus (P), carbon (C) and beryllium (Be) or by a GaN-based semiconductor layer formed by a low temperature process (a temperature of growth less than 800° C.). The material of the high-resistivity GaN-based interlayer 303 includes, for example but not limited to, AlₓIn_{y}Ga_{1-x-y}N, wherein x≧0, y≧0, and 1≧x+y.

In the present embodiment, the GaN-based semiconductor layer 302 is constructed by, for example, but not limited to, a nucleation layer 302a, an ohmic contact layer 302b and an active layer 302c. The nucleation layer 302a is disposed on the substrate 300. The ohmic contact layer 302b is disposed on the nucleation layer 302a and has a second protrusion portion D. The active layer 302c is disposed on the second protrusion portion D. Referring to FIG. 3, a first protrusion portion C of the whole GaN-based semiconductor layer 302 is constructed by the second protrusion portion D of the ohmic contact layer 302b and the active layer 302c. Moreover, a material of the nucleation layer 302a includes, for example, but not limited to, AlₐIn_{b}Ga_{1-a-b}N semiconductor, wherein a, b≧0 and 0≦a+b≦1. The material of the ohmic contact layer 302b includes, for example, but not limited to, N-type Al_{c}In_{d}Ga_{1-c-d}N semiconductor, wherein c, d≧0 and 0≦c+d≦1. The material of active layer 302c includes, for example but not limited to, undoped AlₑIn_{f}Ga_{1-e-f}N semiconductor, wherein e, f≧0 and 0≦e+f≦1.

In the present embodiment, the materials of the first electrode 304 includes, for example, but not limited to, Ni/Au, Cr/Au, Cr/Pt/Au, Ti/Al, Ti/Al/Ti/Au, Ti/Al/Pt/Au, Ti/Al/Ni/Au, Ti/Al/Ti/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au Nd/Al/Co/A, Hf/Al/Ti/Au, Hf/Al/Pt/Au, Hf/Al/Ni/Au, Hf/Al/Pd/Au, Hf/Al/Cr/Au, Hf/Al/Co/Au, Zr/Al/Ti/Au, Zr/Al/Pt/Au, Zr/Al/Ni/Au, Zr/Al/Pd/Au, Zr/Al/Cr/Au, Zr/Al/Co/Au, TiNₓ/Ti/Au, TiNₓ/Pt/Au, TiNₓ/Ni/Au, TiNₓ/Pd/Au, TiNₓ/Cr/Au, TiNₓ/Co/Au, TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAl/Ni/Au, Ti/NiAl/Cr/Au, N-type conductive indium tin oxide (ITO), cadmium tin oxide (CTO), aluminum zinc oxide (ZnO:Al), indium zinc oxide (ZnO:In), zinc gallate (ZnGa₂O₄), SnO₂:Sb, Ga₂O₃:Sn, AgInO₂:Sn, In₂O₃:Zn, P-type conductive CuAlO₂, LaCuOS, NiO, CuGaO₂ or SrCu₂O₂.

FIG. 4 is a diagram illustrating the current-voltage curves of the Schottky barrier diode (SBD) type UV photodetector of the present invention in comparison with that of a prior art measured under non-illuminated condition. Referring to FIG. 4, the forward current and the reverse current are measured under a non-illuminated condition. It is noted that, under the same bias condition (especially in a bias larger than −3V), the leakage current of a prior art is much larger than that of the present embodiment. In the present embodiment, since the GaN-based interlayer is provided for the Schottky barrier diode (SBD) type UV photodetector, the leakage current is drastically reduced due to the excellent insulating property of the GaN-based interlayer and the excellent Schottky contact formed between the GaN-based interlayer and the electrode 304.

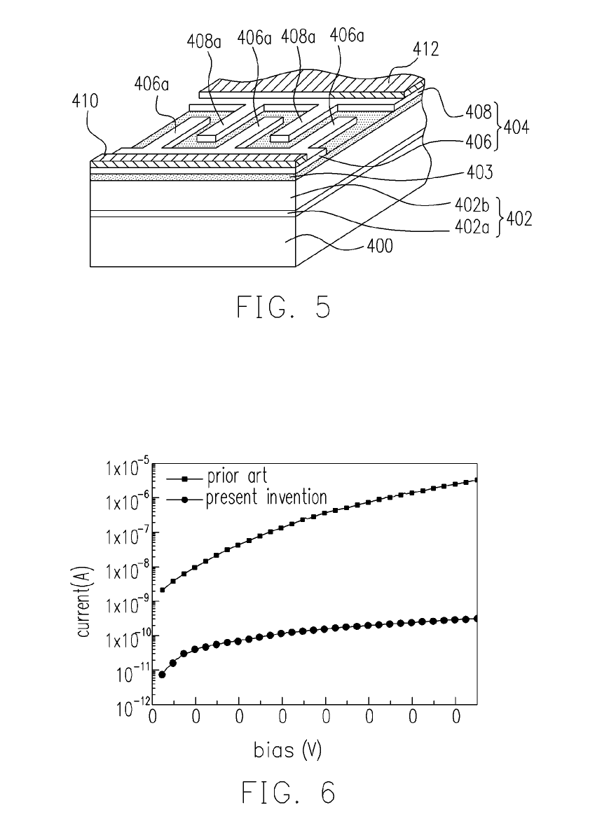

FIG. 5 is a perspective view illustrating a metal-semiconductor-metal (MSM) type UV photodetector according to a preferred embodiment of the present invention. Referring to FIG. 5, a metal-semiconductor-metal (MSM) type UV photodetector comprises a substrate 400, a GaN-based semiconductor layer 402, a GaN-based interlayer 403 and a patterned electrode layer 404. The GaN-based semiconductor layer 402 is disposed on the substrate 400. The GaN-based interlayer 403 is disposed on the GaN-based semiconductor layer 402, and a material of the GaN-based interlayer 403 includes, for example but not limited to, AlₓIn_{y}Ga_{1-x-y}N, wherein x≧0, y≧0, and 1≧x+y. The patterned electrode layer 404 is disposed on the GaN-based interlayer 403. Moreover, in order to simplify the package process, in the present embodiment, a first bonding pad 410 and a second bonding pad 412 can be optionally formed on the first electrode 406 and the second electrode 408 respectively to simplify the wire bonding process. The materials of the first bonding pad 410 and the second bonding pad 412 include, for example, but not limited to, Ti/Au, Cr/Au, Cr/Pt/Au, or another material that can be incorporated with the first electrode 406 and the second electrode 408.

Hereinafter, the electrode of the patterned electrode layer 404 and the GaN-based semiconductor layer will be described. Since the materials of the substrate 400 and the patterned electrode layer 404 are the same as that of the substrate and the GaN-based semiconductor layer described in the above embodiments, detailed description of these materials are omitted.

In the preferred embodiment, the first electrode 406 comprises, for example, a plurality of mutually parallel aligned first finger-shaped protrusions 406a, and the second electrode 408 comprises, for example, a plurality of second finger-shaped protrusions 408a. Moreover, the first finger-shaped protrusions 406a and the second finger-shaped protrusions 408a are, for example, mutually interlaced. The high-resistivity interlayer 403 of the embodiment is constructed by doping at least one dopant selected from a group consisting of iron (Fe), magnesium (Mg), zinc (Zn), copper (Cu), arsenide (As), phosphorus (P), carbon (C) and beryllium (Be) or by a GaN-based semiconductor layer formed by a low temperature process (a temperature of growth less than 800° C.). The material of the high-resistivity GaN-based interlayer 403 includes, for example, AlₓIn_{y}Ga_{1-x-y}N, wherein x≧0, y≧0, and 1≧x+y.

In the present embodiment, the GaN-based semiconductor layer 402 is constructed, for example, by a nucleation layer 402a and an active layer 402b. The nucleation layer 402a is disposed on substrate 400, and the active layer 402b is disposed on the nucleation layer 402a. Moreover, a material of the nucleation layer 402a includes, for example, but not limited to, AlₐIn_{b}Ga_{1-a-b}N semiconductor, wherein a, b≧0 and 0≦a+b≦1. The material of the active layer 402b includes, for example, but not limited to, undoped AlₑIn_{f}Ga_{1-e-f}N semiconductor, wherein e, f≧0 and 0≦e+f≦1.

FIG. 6 is a diagram illustrating the current-voltage curves of the metal-semiconductor-metal (MSM) type UV photodetector of the present invention in comparison with that of a prior art measured under non-illuminated condition. Referring to FIG. 6, the current is measured under a non-illuminated condition. According to FIG. 6, under the same bias condition (especially between 0V to 14V), the leakage current of a prior art is much larger than that of the metal-semiconductor-metal (MSM) type UV photodetector of the present invention. In the present embodiment, since the GaN-based interlayer is provided in the metal-semiconductor-metal (MSM) type UV photodetector, the leakage current is drastically reduced due to the excellent insulating property of the GaN-based interlayer and the excellent Schottky contact formed between the GaN-based interlayer and the electrode.

Accordingly, an UV photodetector provided by the present invention have at least the following advantages. First, since a high-resistivity GaN-based interlayer is provided to reduce the leakage current of the UV photodetector, the performance of the device of the UV photodetector can be enhanced. Moreover, in the present invention, a high temperature thermal treatment process following an epitaxy process is not required during the manufacturing of the GaN-based interlayer, and therefore the process can be simplified.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An UV photodetector, comprising:
a substrate;
a GaN-based semiconductor layer, disposed on the substrate, wherein the GaN-based semiconductor layer comprises a first protrusion portion;
a high-resistivity GaN-based interlayer, disposed on the first protrusion portion of the GaN-based semiconductor layer, and a material of the GaN-based interlayer comprising AlₓIn_{y}Ga_{1-x-y}N, wherein x≧0, y≧0, 1≧x+y;
a first electrode, disposed on the GaN-based interlayer; and
a second electrode disposed on a portion of the GaN-based semiconductor layer except for the first protrusion portion.

2. The UV photodetector of claim 1, further comprising a first bonding pad, wherein the first bonding pad is disposed on the first electrode.

3. The UV photodetector of claim 1, further comprising a second bonding pad, wherein the second bonding pad is disposed on the second electrode.

4. The UV photodetector of claim 1, wherein the substrate is comprised of an aluminum oxide (sapphire) substrate, a silicon carbide (SiC) substrate, a zinc oxide (ZnO) substrate, a silicon substrate, a gallium phosphide (GaP) substrate, and a gallium arsenide (GaAs) substrate.

5. The UV photodetector of claim 1, wherein the high-resistivity GaN-based interlayer is constructed by doping at least one dopant selected from a group consisting of iron (Fe), magnesium (Mg), zinc (Zn), copper (Cu), arsenide (As), phosphorus (P), carbon (C) and beryllium (Be) or by a GaN-based semiconductor layer formed by a low temperature process (a temperature of growth less than 800° C.).

6. The UV photodetector of claim 1, wherein the GaN-based semiconductor layer comprising:
a nucleation layer, disposed on the substrate;
an ohmic contact layer, disposed on the nucleation layer, wherein the ohmic contact layer comprises a second protrusion portion; and
an active layer, disposed on the second protrusion portion, wherein the first protrusion portion is constructed by the second protrusion portion of the ohmic contact layer and the active layer.

7. The UV photodetector of claim 6, wherein a material of the nucleation layer comprises AlₐIn_{b}Ga_{1-a-b}N semiconductor, wherein a, b≧0 and 0≦a+b≦1.

8. The UV photodetector of claim 6, wherein a material of the ohmic contact layer comprises N-type Al_{c}In_{d}Ga_{1-c-d}N semiconductor, wherein c, d≧0 and 0≦c+d≦1.

9. The UV photodetector of claim 6, wherein a material of the active layer comprises undoped AlₑIn_{f}Ga_{1-e-f}N semiconductor, wherein e, f≧0 and 0≦e+f≦1.

10. The UV photodetector of claim 1, wherein a material of the first electrode and the second electrode comprises Ni/Au, Cr/Au, Cr/Pt/Au, Ti/Al, Ti/Al/Ti/Au, Ti/Al/Pt/Au, Ti/Al/Ni/Au, Ti/Al/Ti/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au Nd/Al/Co/A, Hf/Al/Ti/Au, Hf/Al/Pt/Au, Hf/Al/Ni/Au, Hf/Al/Pd/Au, Hf/Al/Cr/Au, Hf/Al/Co/Au, Zr/Al/Ti/Au, Zr/Al/Pt/Au, Zr/Al/Ni/Au, Zr/Al/Pd/Au, Zr/Al/Cr/Au, Zr/Al/Co/Au, TiNₓ/Ti/Au, TiNₓ/Pt/Au, TiNₓ/Ni/Au, TiNₓ/Pd/Au, TiNₓ/Cr/Au, TiNₓ/Co/Au, TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAl/Ni/Au, Ti/NiAl/Cr/Au, N-type conductive indium tin oxide (ITO), cadmium tin oxide (CTO), aluminum zinc oxide (ZnO:Al), indium zinc oxide (ZnO:ln), zinc gallate (ZnGa₂O₄), SnO₂:Sb, Ga₂O₃:Sn, AgInO₂:Sn, In₂O₃:Zn, P-type conductive CuAlO₂, LaCuOS, NiO, CuGaO₂ or SrCu₂O₂.

11. An UV photodetector, comprising:
a substrate;
a GaN-based semiconductor layer, disposed on the substrate;
a high-resistivity GaN-based interlayer, disposed on the GaN-based semiconductor layer, and a material of the GaN-based interlayer comprises AlₓIn_{y}Ga_{1-x-y}N, wherein x≧0, y≧0, 1≧x+y; and
a patterned electrode layer disposed on the GaN-based interlayer.

12. The UV photodetector of claim 11, wherein the patterned electrode layer comprises a first electrode and a second electrode.

13. The UV photodetector of claim 12, wherein the first electrode comprises a plurality of first finger-shaped protrusions, the second electrode comprises a plurality of second finger-shaped protrusions, and the first finger-shaped protrusions and the second finger-shaped protrusions are mutually interlaced.

14. The UV photodetector of claim 12, further comprises a first bonding pad, wherein the first bonding pad is disposed on the first electrode.

15. The UV photodetector of claim 12, further comprises a second bonding pad, wherein the second bonding pad is disposed on the second electrode.

16. The UV photodetector of claim 11, wherein the substrate is comprised an aluminum oxide (sapphire) substrate, a silicon carbide (SiC) substrate, a zinc oxide (ZnO) substrate, a silicon substrate, a gallium phosphide (GaP) substrate, and a gallium arsenide (GaAs) substrate.

17. The UV photodetector of claim 11, wherein the high-resistivity GaN-based interlayer is constructed by doping at least one dopant selected from a group consisting of iron (Fe), magnesium (Mg), zinc (Zn), copper (Cu), arsenide (As), phosphorus (P), carbon (C) and beryllium (Be) or by a GaN-based semiconductor layer formed by a low temperature process (a temperature of growth less than 800° C.).

18. The UV photodetector of claim 11, wherein the GaN-based semiconductor layer comprising:
a nucleation layer, disposed on the substrate; and
an active layer, disposed on the nucleation layer.

19. The UV photodetector of claim 18, wherein a material of the nucleation layer comprises AlₐIn_{b}Ga_{1-a-b}N semiconductor, wherein a, b≧0 and 0≦a+b≦1.

20. The UV photodetector of claim 18, wherein a material of the active layer comprises undoped AlₑIn_{f}Ga_{1-e-f}N semiconductor, wherein e, f≧0 and 0≦e+f≦1.

21. The UV photodetector of claim 11, wherein a material of the patterned electrode layer comprises Ni/Au, Cr/Au, Cr/Pt/Au, Ti/Al, Ti/Al/Ti/Au, Ti/Al/Pt/Au, Ti/Al/Ni/Au, Ti/Al/Ti/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au Nd/Al/Co/A, Hf/Al/Ti/Au, Hf/Al/Pt/Au, Hf/Al/Ni/Au, Hf/Al/Pd/Au, Hf/Al/Cr/Au, Hf/Al/Co/Au, Zr/Al/Ti/Au, Zr/Al/Pt/Au, Zr/Al/Ni/Au, Zr/Al/Pd/Au, Zr/Al/Cr/Au, Zr/Al/Co/Au, TiNₓ/Ti/Au, TiNₓ/Pt/Au, TiNₓ/Ni/Au, TiNₓ/Pd/Au, TiNₓ/Cr/Au, TiNₓ/Co/Au, TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAl/Ni/Au, Ti/NiAl/Cr/Au, N-type conductive indium tin oxide (ITO), cadmium tin oxide (CTO), aluminum zinc oxide (ZnO:Al), indium zinc oxide (ZnO:ln), zinc gallate (ZnGa₂O₄), SnO₂:Sb, Ga₂O₃:Sn, AginO₂:Sn, In₂O₃:Zn, P-type conductive CuAlO₂, LaCuOS, NiO, CuGaO₂ or SrCu₂O₂.
